(19) United States
(12) Patent Application Publication
(10) Pub. No.: US 2008/0196243 A1
(43) Pub. Date: Aug. 21, 2008

(54) Device for Coupling Electromagnetic Radiation from a Source into a Microwave Chamber

(75) Inventors: Markus Brueckl, Freising (DE); Wolfgang Pfeiffer, Freising (DE); Thomas Zwack, Landshut (DE); Alexander Hoette, Hagg (DE); Peter Gruembel, Wang (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GNBH, Freising (DE)

(21) Appl. No.: 11/938,050

(22) Filed: Nov. 9, 2007

(30) Foreign Application Priority Data
Nov. 14, 2006 (DE) 102006053520.0

(51) Int. Cl. H05K 13/04

(52) U.S. Cl. 29/729; 29/739

(57) ABSTRACT

A device for coupling electromagnetic radiation from a source into a microwave chamber (20) is configured to be attached to a window (23) of the microwave chamber (20). The device comprises a waveguide (26) and a shield operable to cover an outer part of the window (23) in such a manner as to prevent electromagnetic radiation passing through the outer part. The shield defines an opening (25) configured to expose an inner part of the window (23) in such a manner as to allow electromagnetic radiation to pass through the inner part from the waveguide (26). The opening (25) has a cross-sectional area substantially equal to the cross-sectional area of the waveguide (26).

### FIELD OF THE INVENTION

The present invention generally relates to a device for coupling electromagnetic radiation from a source into a microwave chamber. More particularly, the present invention relates to a device for attachment to the window of a microwave chamber for guiding microwaves into the microwave chamber.

### BACKGROUND OF THE INVENTION

Plasma-enhanced chemical vapor deposition (PECVD) is used in semiconductor processing to deposit electrodes on integrated circuits as high quality metallic thin films. The electrode material, for example tungsten, must be deposited on the integrated circuit in a plasma chamber in a clean environment. A plasma is created by allowing streams of gases to flow into a vacuum chamber—one gas comprising the metal that it is required to deposit and the other gases being reactant gases. The plasma chamber (process chamber) needs to be cleaned with “clean gas”. Clean gas is produced by exposing NF₃ gas to microwave radiation in a cavity (microwave chamber) connected to the process chamber. The NF₃ is then excited by the microwave radiation to produce free radicals (atomic F).

Electromagnetic (RF) radiation, usually in the microwave region of the spectrum, is coupled through a glass window provided in one side of the chamber, which ionizes the gases in the chamber, thus creating a plasma. The microwaves are guided through the window into the chamber using a waveguide, which, in its simplest form, is a sheet of aluminum with a small slit aperture provided in the center. The cross-sectional area of the slit aperture is smaller than the cross-sectional area of the microwave radiation stream provided to the chamber, so as to guide the microwaves into the chamber.

A conventional device for coupling electromagnetic radiation into a microwave chamber is shown in FIG. 1 to FIG. 3. A microwave chamber (10) has an inlet (11) for allowing gases to enter the chamber (10) and an outlet (12) for exhausting gases from the chamber 10. The outlet is connected to a process chamber (not shown) in which semiconductor wafers are to be processed. A window (13) is provided on the front face of the chamber (10). An outer aluminum plate facing outwardly of the front face of the chamber (10) secures the window (13) to the front face of the chamber (10) and is operable to provide a vacuum seal so that the chamber (10) is airtight once it has been pumped down to the required pressure. The aluminum plate defines an opening, which is a waveguide (16) operable to allow microwave radiation (17), generated by a microwave source (18) so as to have a cross-sectional area 19, to enter the chamber (10).

An inner aluminum plate (14) has an outer sealing rim that is provided with rivet holes so that the inner aluminum plate (14) can be attached to the front face of the chamber (10) on the side of the window (13) that faces into the chamber (10). The aluminum plate (14) defines an opening (15) and acts as a shield which prevents electromagnetic radiation entering the chamber (10) in any other area than through the opening (15). The opening (15) has a cross-sectional area that is much smaller than the cross-sectional area (19) of the waveguide opening (16), thereby providing an arrangement similar to a cavity coupled to a waveguide through a slit or hole.

Semiconductor wafers, upon which tungsten is to be deposited, are placed in the process chamber, which is then pumped down to the required pressure. To clean the process chamber, in order to remove residual tungsten deposits from previous processing runs from the inside of the chamber, a reactant gas, for example NF₃, is fed into the microwave chamber (10) (when it has been pumped down and is under vacuum) through the inlet (11). Microwave radiation RF radiation of around 1250 W from the source (18) is guided through the waveguide opening (16), impinges on the window (13), and is coupled into the chamber (10) through the slit opening (15) in the inner aluminum plate (14). When the high power electromagnetic radiation is fed through the small opening (15), it causes the NF₃ gas fed into the chamber through the inlet (11) to be excited and a clean gas containing atomic F is produced.

When the microwave radiation is coupled into the chamber (10) from the waveguide (16) through the opening (15) in the aluminum plate (14), it is comparable to coupling RF radiation into a resonator cavity through a slit waveguide. It is known in the art that, when RF radiation is coupled into a cavity, a small slit waveguide, like the opening (15) in the aluminum plate (14), is required to achieve a firm coupling of the radiation into the cavity, otherwise the radiation will be reflected back out of the cavity.

With repeated use, the edges of the window (13) become burned due to the intensity of the microwave radiation. In FIG. 1, the conventional device is shown after processing of some wafers, and it can be seen that the edge of the opening (15) is already starting to exhibit wear. In FIG. 2, the device is shown after processing of many wafers and it can be seen that the edges of the opening (15) in the aluminum plate (14) have become burned, and thus eroded. The shape of the opening (15) is then changed and the opening (15) is widened; it is no longer a small slit. Therefore the aluminum plate (14) must be replaced regularly.

Furthermore, when the glass in the window (13) is burned, this results in particles being formed, which become dislodged from the glass surface on the inside of the chamber and can cause contamination of the gas that flows into the process chamber during the tungsten deposition process. However, high power microwave radiation must be used (over 1000 W) so that it is effectively coupled into the microwave chamber (10) through the slit opening (15). This means that the intensity of the radiation that has to be used is such that it eventually will cause burning of the glass in the window (13). Therefore the window (13) also has to be replaced regularly.

### SUMMARY OF THE INVENTION

The present invention has been devised with the foregoing in mind. Thus the present invention provides a device for coupling electromagnetic radiation from a source into a microwave chamber. The device comprises a waveguide and is configured to be attached to a window of the microwave chamber. The device also comprises a shield operable to cover an outer part of the window so as to prevent electromagnetic radiation passing through the outer part of the window covered by the shield. The shield defines an opening configured to expose an inner part of the window in such a manner as to allow electromagnetic radiation to pass through the inner part of the window. The inner part of the window refers to a generally central portion of the window and the outer part of the window refers to a generally peripheral part of the window. The opening has a cross-sectional area substantially equal to the cross-sectional area of the waveguide. In this way, burning of the glass window by the microwave radiation is substantially eliminated.

Preferably, the shield comprises a first substantially circular flat aluminum plate operable to be attached to the window on a side facing inside the microwave chamber. The shield portion further comprises a second substantially circular flat aluminum plate operable to be attached to the window on a side facing outside the microwave chamber. The second plate has a thickness greater than the thickness of the first plate. The second plate can comprise a circumferential sealing means configured to provide a vacuum seal when the device is attached to the window. In this way, the device can be retrofit onto an existing microwave chamber. The opening should be arranged substantially centrally in the shield.

It is surprising that providing an opening into the chamber that has the same cross-sectional area of the waveguide does not cause any of the RF radiation coupled into the chamber to be reflected back out again. As stated above, the chamber is comparable to a resonator cavity and it has always been known in the art that RF radiation will be reflected out of a cavity if it is introduced into the cavity through an aperture any larger than a very small slit or hole. However, surprisingly, the RF radiation stays in the chamber to react with the gases introduced into the chamber so as to form a plasma. Even more surprisingly, lower power RF radiation can be coupled into the chamber when an area of the window is exposed that has the same cross-sectional area as the waveguide. It would be expected that, due to the reflective properties of the chamber, a higher power of radiation would need to be coupled into the chamber to prevent it being reflected back through the larger aperture in the window.

### DESCRIPTION OF THE VIEWS OF THE DRAWING

Further advantages and characteristics of the invention ensue from a description below of a preferred embodiment, and from the accompanying drawings.

FIG. 1 is a front view of a conventional waveguide device after processing of some of wafers.

FIG. 2 is a front view of a conventional waveguide device after further use when many wafers have been processed.

FIG. 3 is a side cross-sectional view of a microwave chamber having a conventional waveguide.

FIG. 4 is a front view of a waveguide device according to the present invention.

FIG. 5 is a side cross-sectional view of a microwave chamber having a waveguide device according to the present invention.

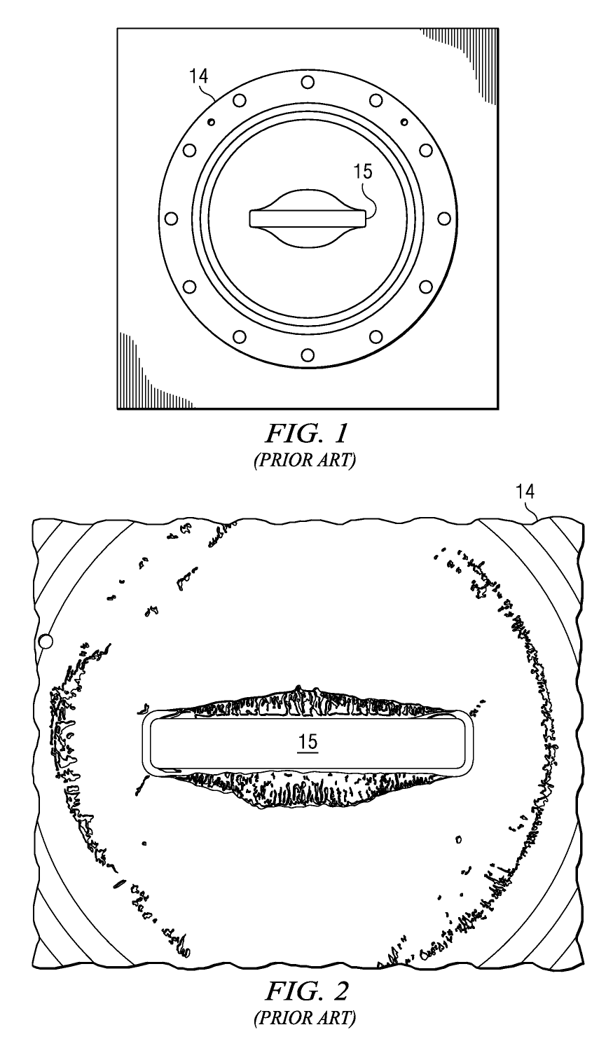

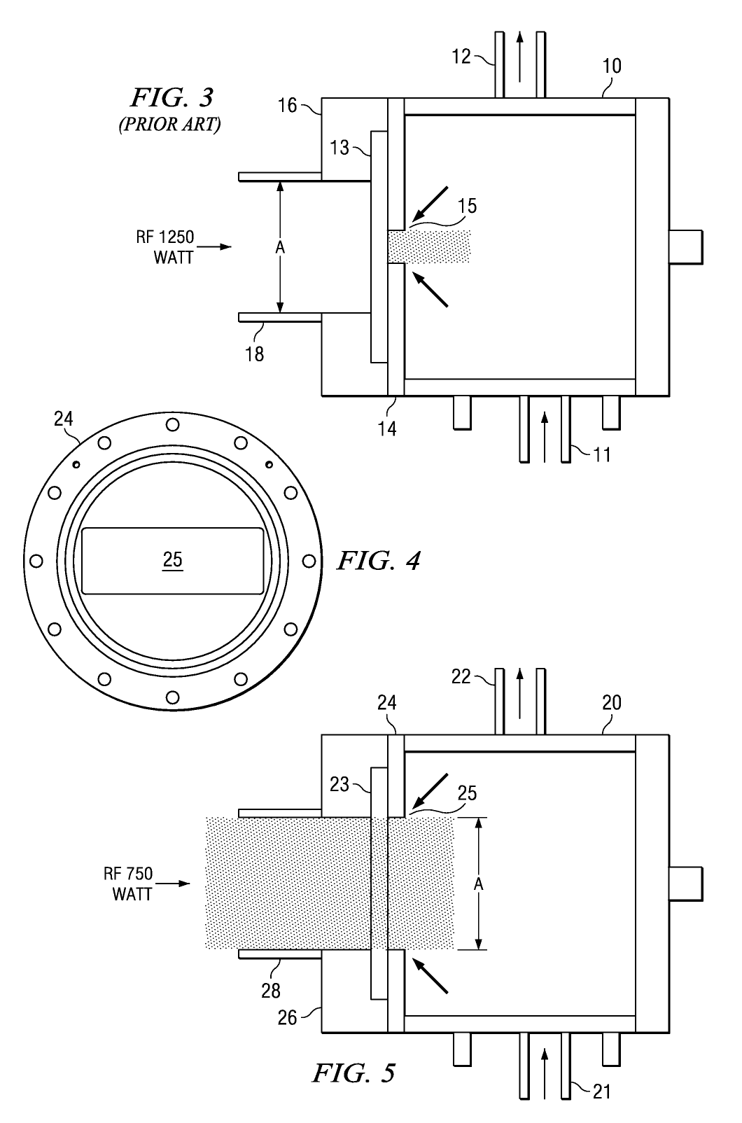

### DETAILED DESCRIPTION

Referring now to FIG. 4 and FIG. 5, a microwave chamber (20) has an inlet pipe (21), which is connected to the chamber (20) in a bottom surface of the chamber (20) and is operable to allow gases to enter the chamber (20). An outlet pipe (22) is connected to the chamber (20) in a top surface of the chamber and is operable to allow gases to exit the chamber (20). The outlet pipe (22) is connected to a process chamber (not shown), in which semiconductor wafers are to be processed.

A window (23) is provided on a front face of the chamber 20. An outer aluminum plate (26) facing outwardly of the front face of the chamber (20) secures the window (23) to the front face of the chamber (20) and is operable to provide a vacuum seal so that the chamber (20) is airtight once it has been pumped down to a required pressure. The aluminum plate (26) defines an opening, which acts as a waveguide (26). The waveguide (26) has a cross-sectional area (29) and is operable to allow microwave radiation, generated by a microwave source (28), to enter the chamber (20).

An aluminum plate (24) is arranged behind the window (23) so that it is provided on the front face of the chamber (20) on a side of the window (23) that faces inside the chamber (20). The aluminum plate (24) is substantially flat and circular, is thinner than the aluminum plate (26), and has an outer rim provided with rivet holes and a groove for receiving an O-ring seal. Thus when the waveguide (24) is attached to the chamber (20), an airtight seal is formed where a outer edge of the waveguide (24) is affixed to the front face of the chamber (20). The aluminum plate (24) forming the waveguide defines a substantially rectangular opening (25). The opening (25) has a substantially same cross-sectional area as the cross-sectional area (29) of the microwave radiation to be coupled into the microwave chamber (20). The aluminum plate (24) acts as a shield, which covers part of the window (23) and prevents microwave radiation entering the chamber (20). Thus the radiation can only enter the chamber (20) via the window (23) through the part of the window (23) that is not covered by the aluminum plate; i.e., through the opening (25).

As with a conventional process described above, the process chamber must be cleaned with clean gas to remove residual tungsten particles on an inside region of the process chamber left from previous processes. The process chamber and the microwave chamber (20) are pumped down to a pressure approaching a vacuum. A stream of reactant gas NF₃, enters the microwave chamber (20) through the inlet pipe (21). Microwave radiation from the source (28) impinges on the window (23) and is then coupled into the chamber (20) by being guided through the opening (25).

As the microwave radiation is coupled into the chamber (20), molecules in the NF₃ gas become excited and atomic F (fluorine gas) is formed. The fluorine gas is exhausted from the microwave chamber (20) through the outlet pipe (22) and cleans the process chamber.

Configuring the opening (25) to have substantially the same cross-sectional area as the waveguide (26) used to couple radiation coupled into the microwave chamber (20) substantially eliminates burning of the window (23) because a lower power of radiation can be used (about 750 W compared with over 1000 W in the conventional device). This is surprising because it would be expected that more radiation would be reflected out of a larger opening to the chamber (20), and therefore that a higher power of radiation than used with a conventional device would have to be coupled into the chamber (20) in the first place.

However, counter-intuitively, the RF radiation is not reflected back out of the chamber (20). Since a lower power of microwave radiation can be coupled into the chamber (20) through the opening (25), this also means that the aluminum plate (24) is not eroded and contamination inside the process chamber due to particles of burned glass coming loose from the surface of the window facing inside the microwave chamber, is substantially eliminated.

Furthermore, with a device according to the present invention, because it is possible to use a lower power of microwave radiation, thermal loading of wafers in the process chamber is considerably reduced.

The device of the present invention can be easily retrofit to an existing microwave chamber using conventional vacuum sealing techniques, with a minimum of process disruption and without having to replace existing chambers.

Because the device of the present invention substantially eliminates burning of glass in a window of a microwave chamber through which RF radiation is coupled, the window and aluminum plate do not have to be replaced so often. This considerably reduces a cleaning time of fabrication processes, as well as RF power required.

Although the present invention has been described with reference to a specific embodiment, it is not limited to this embodiment and no doubt further alternatives will occur to the skilled person which lies within the scope of the invention as claimed.

What is claimed is:

1. A device for coupling electromagnetic radiation from a source into a microwave chamber, the device comprising a waveguide configured to be attached to a window of a said microwave chamber, and further comprising a shield operable to cover an outer part of the window so as to prevent electromagnetic radiation passing through said outer part, the shield defining an opening configured to expose an inner part of the window in such a manner as to allow electromagnetic radiation to pass through said inner part from said waveguide, the opening having a cross-sectional area substantially equal to a cross-sectional area of the waveguide.

2. A device according to claim 1, wherein the shield comprises a first substantially circular flat aluminum plate operable to be attached to the window on a side facing inside the said microwave chamber.

3. A device according to claim 2, wherein the shield further comprises a second substantially circular flat aluminum plate operable to be attached to the window on a side facing outside the said microwave chamber, said second plate having a thickness greater than said first plate.

4. A device according to claim 3, wherein said second plate comprises a circumferential sealing means configured to provide a vacuum seal when the device is attached to the window.

5. A device according to any one of claims 1 to 4, wherein the opening is arranged substantially centrally in the shield.
